(19) United States
(12) Patent Application Publication
(10) Pub. No.: US 2012/0028376 A1
(43) Pub. Date: Feb. 2, 2012

(54) Method of Controlling Critical Dimensions of Trenches in a Metallization System of a Semiconductor Device During Etch of an Etch Stop Layer

(75) Inventors: Mohammed Radwan, Dresden (DE); Johann Steinmetz, Koenigsbrunn (DE)

(73) Assignee: GLOBALFOUNDRIES INC., Grand Cayman (KY)

(21) Appl. No.: 13/157,863

(22) Filed: Jun. 10, 2011

(30) Foreign Application Priority Data
Jul. 30, 2010 (DE) 10 2010 038 736.3

(51) Int. Cl. H01L 21/66

(52) U.S. Cl. 438/5; 257/E21.529

(57) ABSTRACT

When forming metal lines and vias in complex metallization systems of semiconductor devices, an additional control mechanism for adjusting the final critical dimension may be implemented in the last etch process for etching through the etch stop layer after having patterned the low-k dielectric material. To this end, the concentration of a polymerizing gas may be controlled in accordance with the initial critical dimension obtained after the lithography process, thereby efficiently re-adjusting the final critical dimension so as to be close to the desired target value.

### BACKGROUND OF THE INVENTION

1. Field of the Invention

Generally, the present disclosure relates to microstructures, such as advanced integrated circuits, and, more particularly, to conductive structures, such as copper-based metallization layers, comprising metal lines and vias.

2. Description of the Related Art

In the fabrication of modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption and/or diversity of functions. As the size of individual circuit elements is reduced with every new circuit generation, thereby improving, for example, the switching speed of the transistor elements, the available floor space for interconnect lines electrically connecting the individual circuit elements is also decreased. Consequently, the dimensions of these interconnect lines are also reduced to compensate for a reduced amount of available floor space and for an increased number of circuit elements provided per unit die area, as typically the number of interconnections required increases more rapidly than the number of circuit elements. Thus, usually a plurality of stacked “wiring” layers, also referred to as metallization layers, are provided, wherein individual metal lines of one metallization layer are connected to individual metal lines of an overlying or underlying metallization layer by so-called vias. Despite the provision of a plurality of metallization layers, reduced dimensions of the interconnect lines are necessary to comply with the enormous complexity of, for instance, modern CPUs, memory chips, ASICs (application specific ICs) and the like.

Advanced integrated circuits, including transistor elements having a critical dimension of 0.05 μm and even less, may, therefore, typically be operated at significantly increased current densities of up to several kA per cm² in the individual interconnect structures, despite the provision of a relatively large number of metallization layers, owing to the significant number of circuit elements per unit area. Consequently, well-established materials, such as aluminum, are being replaced by copper and copper alloys, i.e., materials with significantly lower electrical resistivity and improved resistance to electromigration, even at considerably higher current densities, compared to aluminum. The introduction of copper into the fabrication of microstructures and integrated circuits comes along with a plurality of severe problems residing in copper's characteristic to readily diffuse in silicon dioxide and a plurality of low-k dielectric materials, which are typically used in combination with copper in order to reduce the parasitic capacitance within complex metallization layers.

Another characteristic of copper significantly distinguishing it from aluminum is the fact that copper may not be readily deposited in larger amounts by chemical and physical vapor deposition techniques and it does not form volatile etch byproducts when exposed to currently established etch processes, thereby requiring a process strategy that is commonly referred to as the damascene or inlaid technique. In the damascene process, first a dielectric layer is formed which is then patterned to include trenches and/or vias which are subsequently filled with copper, wherein, prior to filling in the copper, a conductive barrier layer is formed on sidewalls of the trenches and vias. The deposition of the bulk copper material into the trenches and vias is usually accomplished by wet chemical deposition processes, such as electroplating and electroless plating, thereby requiring the reliable filling of vias with an aspect ratio of 5 and more with a diameter of 0.3 μm or even less in combination with trenches having a width ranging from 0.1 μm to several μm. Electrochemical deposition processes for copper are well established in the field of electronic circuit board fabrication. However, for the dimensions of the metal regions in semiconductor devices, the void-free filling of high aspect ratio vias is an extremely complex and challenging task, wherein the characteristics of the finally obtained copper-based interconnect structure significantly depend on process parameters, materials and geometry of the structure of interest. Since the basic geometry of interconnect structures is substantially determined by the design requirements and may, therefore, not be significantly altered for a given microstructure, it is of great importance to estimate and control the impact of materials, such as conductive and non-conductive barrier layers, of the copper microstructure and their mutual interaction on the characteristics of the interconnect structure so as to insure both high yield and the required product reliability.

In addition, to achieve high production yield and superior reliability of the metallization system, it is also important to accomplish these goals on the basis of a high overall throughput of the manufacturing process under consideration. For instance, the so-called dual damascene process is frequently used, in which a via opening and a corresponding trench are filled in a common deposition sequence, thereby providing superior process efficiency.

In the damascene technique or inlaid technique, typically the patterning of the via openings and the trenches may require sophisticated lithography techniques since the shrinkage of critical dimensions in the device layer, i.e., for transistors and other semiconductor circuit elements, may also require a corresponding adaptation of the critical dimensions of the vias and metal lines to be formed in the metallization system. In some well-established process techniques, a patterning regime may be used which may commonly be referred to as “via first-trench last” approach in which at least a portion of a via opening may be formed first on the basis of a specific etch mask and thereafter a corresponding trench mask may be provided in order to form a corresponding trench in the upper portion of the dielectric material, wherein, depending on the overall process strategy, during the trench etch process, the remaining portion of the via opening may also be completed, while, in other cases, the via opening may be provided such that it extends down to a bottom etch stop layer, which may then be opened after completing the trench etch process.

With reference to FIGS. 1a-1c, a typical configuration and manufacturing strategy for forming critical metallization layers of sophisticated semiconductor devices will now be described in more detail.

FIG. 1a schematically illustrates a cross-sectional view of a semiconductor device 100 in an advanced manufacturing stage. As illustrated, the device 100 comprises a substrate 101 and a semiconductor layer 102, such as a silicon layer, in and above which a plurality of circuit elements 103, such as transistors, resistors, capacitors and the like, are provided. The circuit elements 103 typically comprise any components, such as gate electrode structures and the like, which may be formed on the basis of critical dimensions of 50 nm and less. For example, presently complex semiconductor devices are under development in which a gate length of less than 30 nm is to be implemented when complex field effect transistors are considered. The circuit elements 103 are typically embedded in a dielectric material 111 of a contact level 110, wherein the dielectric material 111 may represent any appropriate material system, for instance based on silicon nitride, silicon dioxide and the like. A plurality of contact elements 112 provide electrical connection of the circuit elements 103 with a metallization system 120 of the device 100. In the manufacturing stage shown, metallization layers 130, 140 of the metallization system 120 are provided, wherein, as previously discussed, corresponding metal features may have to be adapted in size and packing density to the architecture and configuration of the circuit elements 103. For example, the metallization layer 130 may comprise any appropriate dielectric material 131, such as a low-k dielectric material and the like, in which are formed metal lines 132, which may appropriately connect to the contact elements 112. Thus, in densely packed device areas, the contact elements 112 and the metal lines 132 may have lateral dimensions, i.e., at least in the horizontal direction of FIG. 1a, that are comparable in magnitude to the critical lateral dimensions of the circuit elements 103. Similarly, metal lines 142L and vias 142V of the metallization layer 140 are embedded in a dielectric material 141, such as a low-k dielectric material, an ultra low-k (ULK) material and the like, and may appropriately connect to the metal lines 132.

In this respect, a low-k dielectric material is to be considered as a dielectric material having a dielectric constant of 3.0 or less, while typically a ULK material may be understood herein as a dielectric material having a dielectric constant of 2.7 and less. Furthermore, typically an appropriate etch stop material 143, which may also act as a confinement or cap layer for the metal material in various metal features, may be provided in order to appropriately control the complex patterning process for forming at least the vias 142V in the metallization layer 140. The etch stop layer 143 may be provided in the form of a silicon material including nitrogen, carbon, oxygen and the like in order to provide superior etch stop capabilities, while not unduly increasing the overall permittivity of the metallization system 120. For example, a plurality of material compositions, also referred to as BLOK materials (bottom low-k), have been developed with a dielectric constant of 4.0 and less, which may exhibit high etch resistivity with respect to any plasma assisted etch recipes used for patterning low-k dielectric materials, while also providing high copper diffusion blocking effects in order to suppress copper migration into sensitive device areas.

The semiconductor device 100 as illustrated in FIG. 1a may be formed on the basis of the following process strategies. The circuit elements 103 are typically formed by using sophisticated lithography techniques, deposition processes, implantation and etch techniques, wherein, however, many of the associated lithography and etch processes may be performed on the basis of a reduced layer thickness compared to the metallization system 120 and also on the basis of a superior device topography, thereby obtaining the desired critical dimensions frequently without applying sophisticated hard mask and other sacrificial material systems. After completing the circuit elements 103, the device level 110 may be formed by depositing the dielectric material or material system 111 and patterning the same in order to form openings, which may subsequently be filled with an appropriate conductive material, any excess portions thereof may be removed by chemical mechanical polishing (CMP) and the like, thereby providing the electrically insulated contact elements 112. The process of patterning the contact level 110, however, may contribute to a pronounced surface topography, thereby increasingly contributing to very sophisticated process conditions during the subsequent processing of the device 100. Thereafter, the metallization layer 130 may be formed by depositing the dielectric material 131 and patterning the same in order to fill in an appropriate conductive material, such as copper, in combination with any appropriate barrier materials. After the removal of any excess material, the etch stop layer 143 may be deposited, followed by the dielectric material 141, which may also be patterned by sophisticated lithography techniques using any appropriate process strategy, such as a via-first approach and the like, wherein at least two critical lithography steps may have to be performed in order to define the lateral size and position of the vias 142V and of the metal lines 142L. Typically, any such critical lithography processes and the subsequent patterning process for transferring the openings of the resist material finally into the underlying dielectric material may be performed on the basis of well-established control regimes, such as advanced process control (APC) regimes, which are designed such that, based on a moderate amount of measurement data, a control of the process sequence may be achieved, in which the process result, i.e., the critical dimensions of the feature under consideration, may be centered around the target value.

FIG. 1b schematically illustrates a corresponding process control regime for a process flow for forming the metal lines 142L and vias 142V (FIG. 1a). To this end, a manufacturing environment 150 may comprise a plurality of manufacturing and metrology tools in which a resist material may be patterned on the basis of photolithography and wherein finally trenches and via openings may be provided in a low-k dielectric material on the basis of any process strategies. For example, as shown, a first process module 151 may represent a portion of the manufacturing environment 150 in which a plurality of lithography tools and related process tools may be provided in order to form appropriate resist material layers on any substrates, such as the substrate 101. To this end, the module 151 may comprise spin-on process tools for forming one or more resist layers, pre-exposure bake tools, post-exposure bake tools, develop stations and the like. Moreover, the module 151 may comprise one or more lithography tools which may expose the resist material on the basis of respective lithography masks in order to transfer the mask pattern into the resist material. Moreover, a metrology module 152 may be provided, which may include any optical inspection techniques for determining the critical dimensions of the resist features after being processed in the lithography module 151. Hence, the metrology module 152 may provide respective measurement data from selected ones of the substrates 101 processed by the module 151 and may provide the measurement data to a control unit 155, which may, based on the desired CD target value, select an appropriate target value for one process parameter, which may sensitively influence the process result of the process module 151. For example, the control unit 155 may provide a target value for an exposure dose that is to be applied upon processing the substrate 101, wherein the unit 155 may determine the target value of the exposure dose such that, based on the measurement data obtained from the module 152, any substrates 101 to be processed in the module 151 are expected to substantially comply with the CD target value. To this end, the control unit 155 may have implemented therein any predictive model of, for instance, the exposure process in the module 151, which may correlate the measurement data from the module 152 with the desired CD target value. Moreover, the environment 150 may comprise a rework module 153, which may receive any substrates 101A which may not be within a valid range of the critical dimensions and which are thus expected to be outside of the specifications after finally transferring the critical dimensions of the resist layers into any lower-lying material in an etch module 156.

It should be appreciated that the lithography module 151 has a somewhat unique position in the whole manufacturing sequence for forming complex microstructure devices since the resist material may be efficiently removed without significantly affecting any underlying material layers, such as dielectric materials and the like, by enabling a further application of resist material in order to re-process the corresponding substrates in the lithography module 151. To this end, however, a plurality of additional process steps, such as cleaning processes and the like, may be required in the rework module 153, which may thus contribute to the overall production costs. Similarly, the processing of the substrates 101 in the lithography module 151 may represent one of the most cost-intensive process modules so that undue increase of the number of substrates to be reworked may significantly affect overall throughput and thus production cost of the manufacturing environment 150.

FIG. 1c schematically illustrates a further portion of the manufacturing environment 150 in which a further metrology module 157 may be provided downstream of the etch module 156 in order to provide measurement data of the finally implemented critical dimensions, i.e., of any via openings and trenches formed in the low-k dielectric material of the metallization system of the substrate 101. It should be appreciated that the possibility of reworking any substrates after having been processed in the module 156 are very limited, since typically the removal of any invalidly patterned low-k dielectric materials may be difficult to achieve without significantly affecting any further device areas, such as lower-lying metallization layers and the like. The measurement data obtained from the module 157 may be supplied to a further control unit 158, which may provide appropriate target values for one or more etch parameters for at least the etch step for patterning the low-k dielectric material under consideration. The control unit 158 may thus mainly strive to provide an etch result that is strongly correlated to the critical dimension obtained after the lithography module 151 for a substrate, which may be forwarded to the etch module 156 if complying with the predefined valid range of critical dimensions determined by the metrology module 152 (FIG. 1b).

As a consequence, appropriate control regimes may be applied, for instance by using statistical process control techniques and the like, in combination with APC strategies in order to provide the final openings in the low-k dielectric material with actual lateral dimensions that may be distributed around the target values, wherein the spread of the distribution may indicate the quality of the overall process flow and thus also of the control mechanisms. It should be appreciated that a significant spread of the lateral dimensions of the corresponding openings may grossly affect the electrical performance of the resulting metallization system since, for instance, line resistance, parasitic capacitance and the like may be strongly correlated with the lateral dimensions of the resulting metal features.

Therefore, significant efforts are being made in reducing the overall process fluctuations during the complex process sequence for patterning sophisticated metallization layers. For example, frequent maintenance of hardware resources, such as etch tools and the like, may have to be implemented into the overall process flow in order to reduce the deviation of critical dimensions of openings, such as trenches, from the target values. Similarly, great efforts are being made in avoiding process non-uniformities during the complex lithography sequence since an increased variability of the critical dimensions of the resist masks used for forming trenches and vias may contribute to an increased reworking of substrates, which may be highly undesirable, since photolithography processes typically represent a very cost-intensive production step. Upon further shrinking the critical dimensions in complex metallization systems, the increasing spread of the critical dimensions, for instance of metal lines, may thus increasingly contribute to yield losses or to a significant spread in performance of the resulting semiconductor devices, thereby reducing the number of semiconductor products that may be assigned to a specific performance segment.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques in which superior control of critical dimensions of at least any trenches, and thus metal lines, in sophisticated metallization systems may be accomplished by implementing an additional control mechanism for adjusting the critical dimensions of trenches in sophisticated dielectric materials. For this purpose, an etch process for opening an etch stop layer of a metallization layer may be efficiently used for adjusting the critical dimension of a trench that is formed in the overlying low-k dielectric material. The control of the etch process for etching through the etch stop material may be established on the basis of a polymerizing gas component, which may be added or the supply thereof may be controlled so as to obtain a desired final width for any given dimension of the corresponding mask that may have been formed on the basis of well-established lithography techniques. That is, due to the additional control mechanism for adjusting the width of the trench and thus the critical pitch of metal lines in densely packed device regions, an increased variability, whether implemented intentionally or accidentally, may be used, while the final critical dimension may be efficiently adjusted on the basis of the etch process for etching through the etch stop layer. For example, by means of the polymerizing gas component, which may be added during the etch process for etching through the etch stop layer, a significant reduction of the previously formed trench portion may be achieved, thereby enabling desired adaptation of the final critical dimension if, for instance, the initial etch mask of the trench is considered inappropriate for the desired final critical dimension. For example, a reduction of the critical dimension of up to 30 percent of the initial critical dimension of the etch mask or even more may be accomplished by creating appropriate “deposition” conditions during the etch process by providing the polymerizing gas component. In other cases, generally a basic polymerizing gas flow may be established during the etch process and the corresponding gas flow may be reduced, thereby providing the possibility of increasing the final critical dimensions when the initial width is considered too small. Consequently, by implementing the additional control mechanism on the basis of the etch process for etching through the etch stop material, a tight distribution of the final critical dimensions around the target value may be achieved, while, at the same time, the range of acceptable “input” critical dimensions of an etch mask may be increased.

One illustrative method disclosed herein comprises performing a first etch process so as to form a trench in a low-k dielectric material of a metallization layer for a semiconductor device and to deepen a via opening so as to extend to an etch stop layer that is formed below the low-k dielectric material. The method further comprises performing a second etch process so as to etch through the etch stop layer. Additionally, the method comprises adjusting the lateral size of the trench by controlling a flow rate of a polymerizing gas in the second etch process.

A further illustrative method disclosed herein relates to forming a via opening and a trench in a low-k dielectric material of a metallization layer of a semiconductor device. The method comprises receiving measurement data indicating a lateral size of a via etch mask and/or a trench etch mask. The method further comprises determining a target flow rate of a polymerizing gas component for an etch process by using the measurement data, wherein the etch process is configured to etch through an etch stop layer that is formed below the low-k dielectric material. The method further comprises forming the via opening and the trench opening in the low-k dielectric material, wherein the via opening exposes a portion of the etch stop layer. Furthermore, the method comprises performing the etch process by using the target flow rate of the polymerizing gas component.

A yet further illustrative method disclosed herein comprises forming a trench hard mask above a dielectric material of a semiconductor device. Furthermore, the method comprises forming a portion of a via opening in the dielectric material through the hard mask opening. Additionally, a trench is formed in the dielectric material while a depth of the via opening is increased so as to extend to an etch stop layer. The method further comprises adjusting a lateral dimension of the trench by etching through the etch stop layer and controlling at least one process parameter.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device comprising a complex metallization system including metal lines and vias formed in a low-k dielectric material;

FIGS. 1b and 1c schematically illustrate a manufacturing environment that is appropriately equipped for performing the complex manufacturing sequence for patterning a low-k dielectric material on the basis of sophisticated conventional process strategies;

FIGS. 2a-2d schematically illustrate cross-sectional views of a semiconductor device during various manufacturing stages in forming a trench and a via opening in a low-k dielectric material of a metallization layer, according to illustrative embodiments;

FIGS. 2e-2h schematically illustrate cross-sectional views of the semiconductor device when forming trenches without vias or at positions in which vias are not provided, according to illustrative embodiments;

FIG. 2i schematically illustrates a cross-sectional view of the semiconductor device according to further illustrative embodiments in which a via etch mask may be formed on the basis of a process sequence in which an anti-reflective coating (ARC) layer may be used for adjusting the critical dimensions of via openings, in addition to adjusting the via openings on the basis of an etch process for opening the etch stop material; and

FIG. 2j schematically illustrates a manufacturing environment that is configured to perform the controlled etch process for etching through the etch stop layer, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure addresses the problem of increased variability of critical dimensions of metal lines in highly complex semiconductor devices by implementing an additional control mechanism for adjusting the critical dimensions of trenches upon patterning sophisticated low-k dielectric materials of metallization systems. To this end, an etch process that may be positioned at a very late stage of the overall patterning process for forming the vias and trenches may be used for efficiently re-adjusting the final critical dimension. That is, upon etching through the etch stop layer of the metallization layer under consideration, a reactive process ambient may be established in which the lateral removal rate and/or lateral “deposition” by polymer species may be controlled on the basis of a polymerizing gas component, thereby also efficiently adjusting the corresponding process parameters for the low-k dielectric material. For example, if the initial critical dimension of an etch mask used to pattern the trenches in the low-k dielectric material has been identified as too large, the addition or the increase of a concentration of the polymerizing gas component may result in the generation of an increased amount of polymer species, preferably at sidewalls of the previously formed openings, thereby reducing the width thereof. The control of the polymerizing gas component may be based on appropriate process information, such as measurement data, which may indicate the critical dimensions after the lithography process, wherein even an increased variability of the corresponding critical dimension after the lithography process may be appropriately compensated for by the additional control mechanism. In this way, an increased allowable range of critical dimensions of the lithography may be established, which may reduce the efforts in terms of replacement of hardware components, performing additional cleaning steps and the like, during the previous process sequence, while at the same time a superior distribution of the resulting final critical dimensions around the target critical dimension may be achieved.

In some illustrative embodiments disclosed herein, in addition to adjusting the critical dimensions of trenches and vias during the final etch process for etching through the etch stop material, an etch mask for the via openings may be formed on the basis of an etch process in which a desired re-adjustment of the critical dimension independently from the corresponding lithography mask may be implemented. To this end, a silicon-containing ARC material may be appropriately patterned so as to adjust a desired critical dimension of a hard mask material that may be used during the patterning of the low-k dielectric material so as to form at least an upper portion of the via openings. In this manner, a certain degree of independence for controlling the trenches and the via openings may be provided, thereby increasing the overall flexibility in adjusting the critical dimensions of the metal features in complex metallization systems.

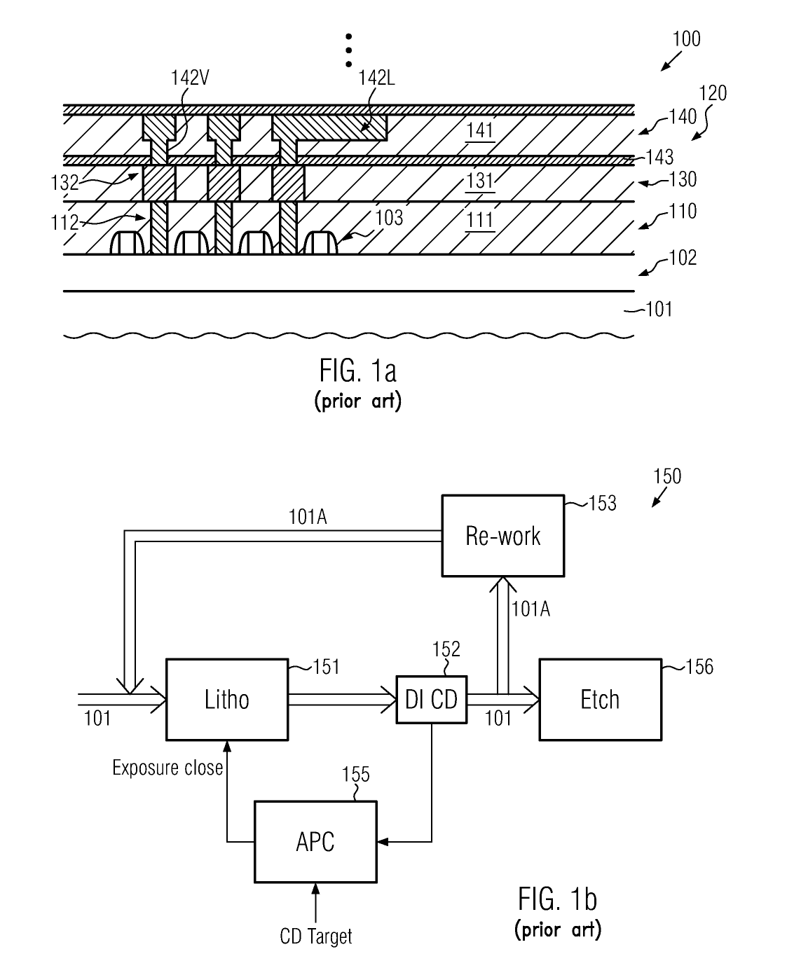

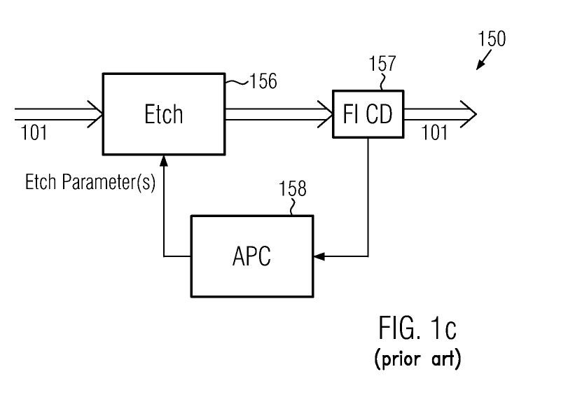

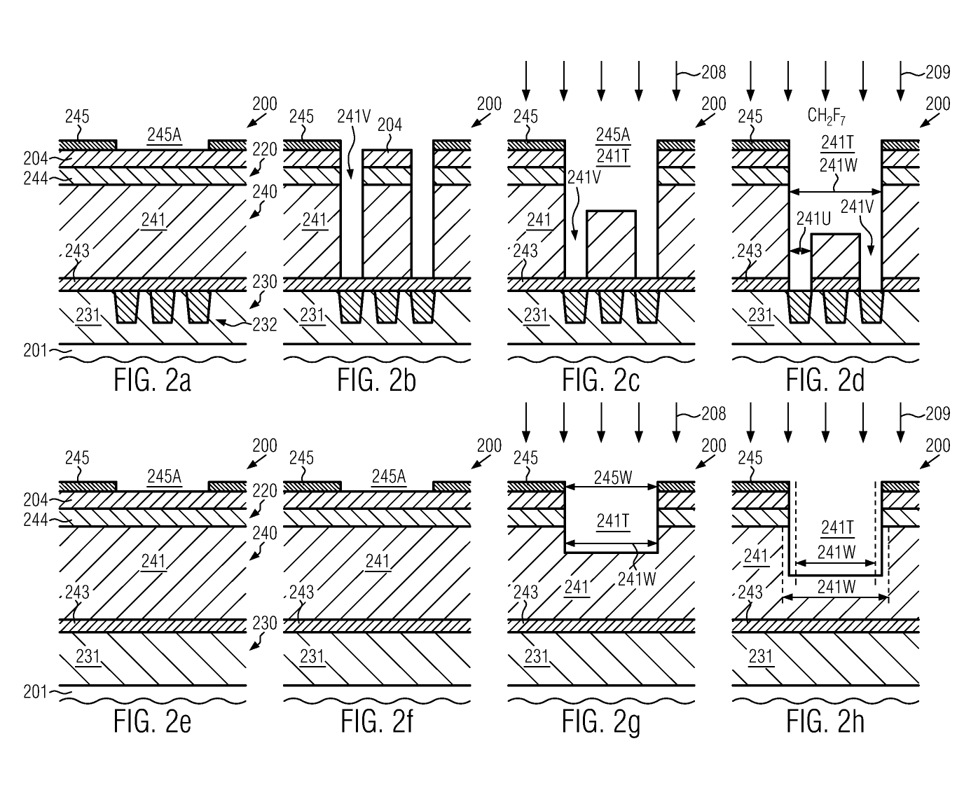

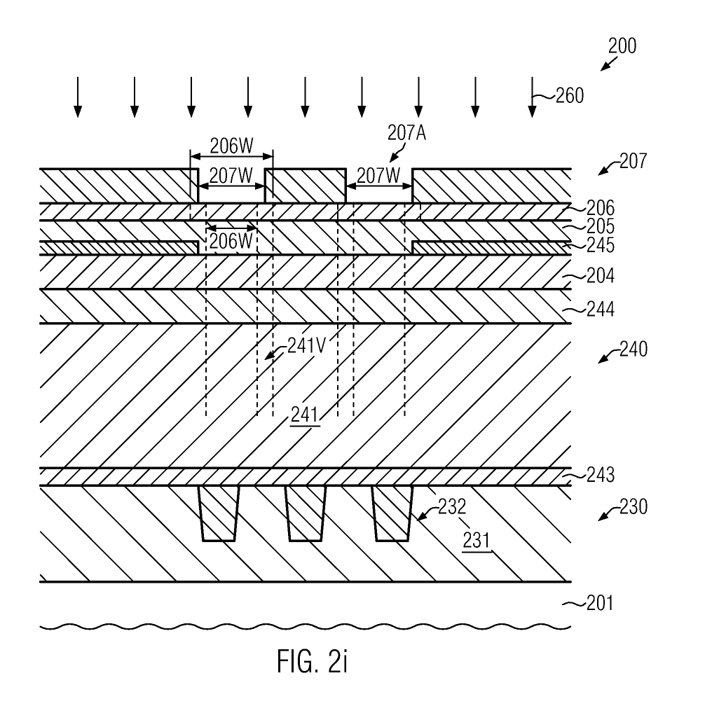

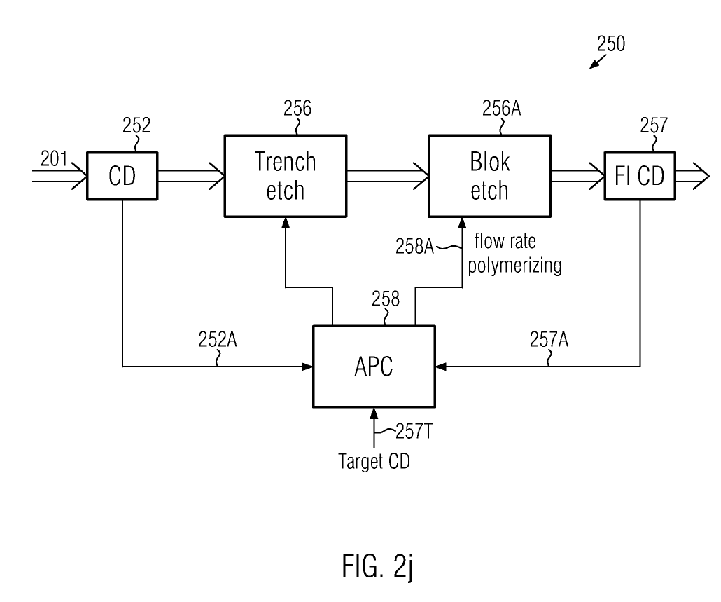

With reference to FIGS. 2a-2i, further illustrative embodiments will now be described in more detail, wherein reference may also be made to FIGS. 1a-1c, if appropriate.

FIG. 2a schematically illustrates a cross-sectional view of a semiconductor device 200 comprising a substrate 201 above which may be formed a metallization system 220 that may comprise, in the manufacturing stage shown, a first metallization layer 230 and a second metallization layer 240. Furthermore, it should be appreciated that typically a semiconductor layer may be formed above the substrate 201, in and above which circuit elements may be provided, such as transistors, resistors, capacitors and the like, in accordance with the overall layout of the device 200. For instance, circuit elements may be provided on the basis of critical dimensions of 50 nm and significantly less, as is also previously discussed with reference to the semiconductor device 100 in FIG. 1a. Similarly, the metallization layer 230 may comprise any appropriate dielectric material 231, such as a low-k dielectric material, a ULK material and the like, in which metal lines 232 may be provided, for instance in the form of metal lines comprising a highly conductive core metal, such as copper and the like, possibly in combination with one or more appropriate barrier materials. Furthermore, in the manufacturing stage shown, the metallization layer 240 may comprise a low-k dielectric material 241 or a ULK material in combination with an etch stop layer 243, for instance provided in the form of a BLOK layer (bottom low-k layer) which may have a dielectric constant of 4.0 and less and which may comprise any appropriate materials, such as silicon, nitrogen, oxygen, hydrogen and the like, as is also previously discussed. Furthermore, the metallization layer 240 may comprise a cap material 244 when the mechanical and/or chemical stability of the low-k dielectric material 241 is considered inappropriate for the further processing of the device 200. It should be appreciated that typically a reduced dielectric constant of a material may be associated with a reduced chemical and/or mechanical stability, since frequently many ULK materials may be provided on the basis of a porous structure, which may result in a certain degree of damage upon performing certain processes, such as CMP, etch processes and the like. For example, the cap layer 244 may be provided in the form of a silicon oxide-based material and the like. Furthermore, in some illustrative embodiments, an additional material layer 204, which may also act as a hard mask material, may be provided above the low-k dielectric material 241, for instance in the form of a silicon dioxide material. Additionally, an etch mask 245 may be provided above the low-k dielectric material 241, wherein, in some illustrative embodiments, the mask material 245 may be provided in the form of a metal-containing material, such as tantalum nitride, titanium nitride, tantalum, aluminum, titanium and the like. It is well known that many of these materials may represent well-established metal-containing materials, for instance used as efficient conductive barrier materials and the like, so that respective material characteristics are well known. For example, it is well known that many of these materials may exhibit a high etch resistivity with respect to a plurality of plasma-based etch recipes that are used for etching the low-k dielectric material 241, thereby enabling a relatively reduced layer thickness for the mask 245, while nevertheless providing an efficient etch resistivity. On the other hand, the mask 245 may be removed on the basis of a plurality of wet chemical etch recipes with a high degree of selectivity with respect to the low-k dielectric material 241 and the cap material 244, if provided. In the manufacturing shown, the mask 245 may have appropriate openings 245A, which substantially determine the lateral size and position of a trench to be formed in the low-k dielectric material 241.

The semiconductor device 200 as shown in FIG. 2a may be formed on the basis of any appropriate process strategy, as is, for instance, also described above with reference to the semiconductor device 100. In particular, the layer stack of the metallization layer 240 may be provided on the basis of well-established deposition techniques, while the mask 245 may be formed on the basis of a complex lithography process, in which an appropriate resist material may be patterned according to the requirements of sophisticated lithography techniques, as discussed above. Due to the very reduced thickness of the layer 245, the resist material may provide sufficient etch resistivity in order to allow an efficient patterning of the material 245, possibly in combination with any ARC materials and other sacrificial material layers. Thereafter, an appropriate etch mask (not shown) may be provided in order to define the lateral size and position of via openings to be formed in the material 241, wherein, as previously discussed, a corresponding etch mask may be formed on the basis of lithography techniques, thereby resulting in a certain degree of process fluctuations in terms of alignment and critical dimension. For example, a corresponding etch mask may be formed on the basis of ARC materials, resist materials and the like, as will also be described later on in more detail with reference to FIG. 2i. For example, a corresponding etch mask may be used to transfer a corresponding mask pattern into the material layer 204 within the trench opening 245A so that finally the mask 245 may be used for the etch process for transferring the via pattern into the lower-lying material 241.

FIG. 2b schematically illustrates the device 200 in a further advanced manufacturing stage. As illustrated, a portion of via opening 241V may be formed in the material 244, if provided, and in the low-k dielectric material 241, wherein the via opening 241V may extend to a desired depth, which may enable completion of the via openings 241V during a subsequent trench patterning process. It should be appreciated that the critical dimensions of the via openings 241V may be substantially determined by the corresponding etch mask (not shown) and the parameters of a corresponding etch process.

FIG. 2c schematically illustrates the semiconductor device 200 when exposed to a reactive etch ambient 208, in which, in a first phase, the layer 204 may be open, for instance, based on well-established etch recipes for etching through silicon dioxide material, followed by the cap layer 244, if provided. Thereafter the low-k dielectric material 241 may be etched, for instance by using a similar etch recipe as previously used for forming the via openings 241V. For example, carbon and fluorine-containing precursor gases may be used, for instance in combination with argon, nitrogen and the like, while also selecting an appropriate plasma power, pressure and temperature. It should be appreciated that a plurality of etch recipes for etching, for instance, silicon dioxide-based low-k dielectric material or ULK materials are available and may be used. Appropriate process parameters may be readily established by using any such recipes or by performing experiments, for instance by using the above-specified etch chemistries. Consequently, during the etch process 208, the via openings 241V may be deepened so as to finally extend to the etch stop layer 243, while at the same time a trench 241T may be formed in the upper portion of the low-k dielectric layer 241. Due to the substantial anisotropic nature of the etch process 208, the critical dimension of the trench 241T may be substantially determined by the etch mask 245, wherein, however, as discussed above, a certain spread in the lateral dimensions of the mask 245 may have been induced due to any process fluctuations during the preceding processing. Since the final critical dimension of the trench 241T may be adjusted in a subsequent etch process, a further re-adjustment of the critical dimension may be accomplished, thereby finally obtaining a narrow distribution around a desired final critical dimension, even if an increased range of variability of the critical dimensions of the mask 245 may be accepted.

FIG. 2d schematically illustrates the semiconductor device 200 when exposed to a further reactive etch ambient 209, in which an appropriate etch chemistry may be applied so as to etch through the etch stop layer 243. To this end, any well-established basic etch chemistries may be applied, for instance on the basis of sulfur fluoride (SF₆) and oxygen, depending on the composition of the etch stop layer 243. It should be appreciated that the layer 243 may typically be comprised of a silicon, carbon and nitrogen-containing material, which may be deposited and treated so as to provide low permittivity, while in other cases material systems including two or more sub-layers may be used. During the etch process 209, the desired width 241W of the trench 241T may be adjusted by controlling at least one process parameter, such as the flow rate, for a given process pressure of a polymerizing gas component, which may have a significant influence on the lateral etch rate and/or deposition rate. That is, upon adding a polymerizing gas component, such as CHₓF_{y}, for instance in the form of CHF₃, CH₂, F₂, CH₃F and the like, a more or less pronounced inert polymer layer may be formed on sidewalls of the trench 241T and also of the vias 241V, while a corresponding material layer may be removed by the ion bombardment during the plasma-based etch process 209. Consequently, by adding the polymerizing gas, the lateral etch rate may be reduced or may be made to zero, or even a “negative” etch rate, i.e., a certain degree of material deposition may be established. For example, upon designing a basic etch recipe for the process 209 such that a desired etch behavior is obtained on the basis of a certain basic concentration of a polymerizing gas, starting from this recipe, an increase of the width 241W may be obtained by reducing the corresponding gas flow rate or by discontinuing the supply thereof to the ambient 209, while a reduction of the width 241W may be obtained by increasing the flow rate of the polymerizing gas component. In this manner, an efficient mechanism may be implemented for re-adjusting the final width 241W at a very advanced stage of the overall patterning process for forming the trench 241T and the via openings 241V. It should be appreciated that also a width 241U of the vias 241V may be influenced by the control of the polymerizing gas component so that also a further control mechanism may be applied in order to re-adjust the width of the via openings 241V, as may be obtained after the initial etch process, the result of which is illustrated in FIG. 2b.

FIG. 2e schematically illustrates the semiconductor device 200 for the above-described process sequence for trenches which may not require a vertical connection to the lower-lying metallization layer. That is, the layer 204 may not be patterned within the opening 245A for forming any via openings.

FIG. 2f schematically illustrates the device 200 for the trench or trench portion without any vias after the via etch process, which may result in the via openings 241V, as shown in FIG. 2b, at any positions in which via openings are required for connecting to the lower-lying metallization layer.

FIG. 2g schematically illustrates the device 200 during the etch process 208, which may be etched through the layers 204 and 244 and finally into the low-k dielectric material 241, thereby forming the trench 241T having an initial width 241W which may be substantially determined by the width 245W of the etch mask 245 and the parameters of the etch process 208.

FIG. 2h schematically illustrates the device 200 during the etch process 209, which may be performed on the basis of a controlled gas flow rate of a polymerizing gas component, as described above. Consequently, the width 241W may be adjusted, i.e., increased or decreased, depending on the initial width of the mask 245, as, for instance, shown as 245W in FIG. 2g.

Consequently, since the control of the etch process 209 (FIGS. 2h and 2d) may be established on the basis of process information indicating the status of the device after the lithography process, thereby also representing the width of the etch mask 245 (FIG. 2g), a wide variety of critical dimensions of the etch mask 245 may be acceptable and may be re-adjusted to a desired final width of the trench 241T, thereby obtaining desired narrow distribution of the final critical dimension around the desired target value.

FIG. 2i schematically illustrates the semiconductor device 200 in a process stage in which via openings 241V may be formed in a portion of the dielectric material 241. As illustrated, the device may comprise an optical planarization material 205, which may be provided in the form of an organic material and the like, followed by a silicon-containing ARC layer 206, above which may be provided a resist material 207 in which corresponding mask openings 207A may be provided. As previously discussed, critical lithography processes may be performed on the basis of a reduced exposure wavelength, for instance presently 193 nm may be used for critical exposure processes, thereby requiring resist materials which may have to be provided with reduced thickness in order to address the reduced depth of focus and other optical characteristics for transferring the mask pattern into resist material 207. To this end, typically, an efficient ARC material may be required, which may have to provide superior surface topography and which may efficiently suppress any back reflection into the resist material 207. To this end, preferably an organic material may be used for providing superior surface planarity, which may be provided with sufficient thickness on the basis of spin-on techniques, while on the other hand a desired high etch resistivity may be provided on the basis of an additional ARC layer, which may have incorporated therein an inorganic component, such as silicon. In this manner, the pattern of the layer 207 may be efficiently transferred into the silicon-containing ARC layer 206, which may subsequently be used as an etch mask for etching through the organic material 205 and finally into the layer 204, which may then be used as a hard mask for forming the via openings 241V. In the embodiment shown in FIG. 2i, at least the etch process 260 for patterning the silicon-containing ARC layer 206 may be performed on the basis of an etch recipe in which the resulting width 206W of the openings in the layer 206 may be efficiently controlled, substantially irrespective of the “incoming” width of the openings 207A in the resist material 207, thereby providing an additional control mechanism. For example, the etch process 260 may be performed as a two-step etch process by using a carbon and fluorine-containing gas, for instance in combination with a polymerizing gas component such as CH₂F₂ and oxygen. Consequently, in a corresponding etch step, for instance, the oxygen concentration may be appropriately adjusted in order to control the lateral etch rate, thereby enabling an efficient variation of the width 206W. In a second step, a carbon and fluorine gas component, possibly in combination with a carbon, hydrogen and fluorine-containing gas may be applied, without using oxygen species in order to avoid undue etching of the underlying material 205, wherein, in this case, the polymerizing gas component may be controlled so as to adjust the finally obtained width 206W. In this manner, the via openings 241V may be formed in an upper portion of the material 241, irrespective of the variability of the critical dimensions of the resist material 207 and may thus allow a different initial width of the via openings, which may then be further varied during the etch process 209 (FIG. 2d), wherein the desired degree of variation in lateral dimensions may be specifically selected with respect to obtaining a desired trench width, while on the other hand the width 241U (FIG. 2d) may be the combination of the control mechanisms provided during the etch process 260 in FIG. 2i and the process 209 in FIG. 2d.

FIG. 2j schematically illustrates a portion of a manufacturing environment 250 in which the above-described additional process control mechanism may be implemented. As illustrated, an etch module 256 may be provided, which may receive the substrate 201 as shown, for instance, in FIGS. 2b, 2f. The substrates 201 may have been subjected to a metrology process in a module 252, which may provide measurement data 252A, thereby indicating the status of the critical dimensions at least after the photolithography process. Furthermore, an etch module 256A may be provided which may be appropriately equipped so as to perform at least the etch process 209 as shown in FIGS. 2d and 2h, in which at least one process parameter may be controlled so as to obtain a desired final critical dimension, which may be determined on the basis of a measurement module 257, which may thus provide corresponding measurement data 257A to a control unit 258. The control unit 258 may represent any appropriate APC mechanism, which may operate the module 256, for instance on the basis of well-established conventional process strategies, and the module 256A on the basis of at least the input measurement data 252A and a target value for the critical dimension, indicated by 257T. For example, the controller 258 may have implemented therein a predictive model for the etch process formed in the module 256A, wherein the corresponding process model may correlate at least one process parameter, such as the flow rate or concentration of a polymerizing gas, with a process result in terms of a critical dimension, for instance due to a modification of the lateral etch rate/deposition rate. Consequently, at least based on the model and the input data 252A, the controller 258 may provide a re-adjusted target value 258A for the at least one control process parameter, such as the flow rate of the polymerizing gas, in order to predict a process result that is close to the target value 257T. In this manner, a feed forward control loop may be established by the controller 258 on the basis of the measurement data 252A for the etch module 256A. It should be appreciated that also the feedback measurement data 257A may be used for enhancing overall control efficiency for the block 256A. Moreover, the data 257A may also be used for controlling the module 256, as is also previously discussed.

As a result, the present disclosure provides manufacturing techniques in which a superior distribution of the final critical dimensions of trenches formed in low-k dielectric materials may be achieved for a wider range of incoming critical dimensions after the critical lithography process, thereby enhancing overall performance of the semiconductor devices, while at the same time increasing overall process throughput by reducing the number of additional wet cleaning processes, reducing the number of maintenance events and by increasing the range of acceptable lithography fluctuation, which may result in a reduced degree of reworking. To this end, the final etch step for etching through the etch stop layer may be controlled on the basis of a polymerizing gas component in order to adjust the lateral etch/deposition rate, which may result in a desired control of the finally obtained critical dimension of the trenches and thus also of the pitches of trenches in densely packed device areas. On the basis of the trenches and via openings, which may comply with a given target value, the processing may be continued with superior process uniformity by filling the openings with an appropriate material system so that, after the removal of any excess metal, the corresponding metal lines and vias may have superior performance and uniformity compared to conventional strategies.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
performing a first etch process so as to form a trench in a low-k dielectric material of a metallization layer of a semiconductor device and to deepen a via opening so as to extend to an etch stop layer formed below said low-k dielectric material;
performing a second etch process so as to etch through said etch stop layer; and
adjusting a lateral size of said trench by controlling a flow rate of a polymerizing gas in said second etch process.

2. The method of claim 1, further comprising forming a hard mask above said low-k dielectric material, wherein said hard mask comprises a trench mask opening having a second lateral size that differs from said lateral size.

3. The method of claim 2, wherein said hard mask is formed from a metal-containing material.

4. The method of claim 1, wherein adjusting a lateral size of said trench comprises receiving measurement data after performing a lithography process used to form said hard mask and determining a target value of said flow rate by using said measurement data.

5. The method of claim 1, wherein said polymerizing gas comprises carbon, hydrogen and fluorine.

6. The method of claim 1, wherein said lateral size is approximately 100 nm or less.

7. The method of claim 1, further comprising forming said via opening so as to extend into said dielectric material by using an etch mask having a via mask opening.

8. The method of claim 7, wherein forming said via opening so as to extend into said dielectric material comprises performing an etch process and controlling at least one process parameter so as to adjust a lateral size of said via mask opening.

9. The method of claim 8, wherein said second etch process is performed so as to comprise at least a first etch step based on a first reactive process ambient and a second etch step based on a second reactive etch ambient that differs from said first reactive etch ambient.

10. The method of claim 1, wherein said dielectric material has a dielectric constant of 2.7 or less.

11. A method of forming a via opening and a trench in a low-k dielectric material of a metallization layer of a semiconductor device, the method comprising:
receiving measurement data indicating a lateral size of at least one of a via etch mask and a trench etch mask;
determining a target flow rate of a polymerizing gas component for an etch process by using said measurement data, said etch process being configured to etch through an etch stop layer, said etch stop layer being formed below said low-k dielectric material;
forming said via opening and said trench in said low-k dielectric material, said via opening exposing a portion of said etch stop layer; and
performing said etch process by using said target flow rate of said polymerizing gas component.

12. The method of claim 11, wherein forming said via opening and said trench comprises forming a hard mask comprising a trench mask opening.

13. The method of claim 12, wherein said hard mask is formed from a metal-containing material.

14. The method of claim 11, wherein forming said via opening comprises forming a second hard mask comprising a via mask opening.

15. The method of claim 11, wherein determining said target flow rate comprises determining a flow rate so as to reduce an effective lateral size of said via opening and said trench compared to the lateral size indicated by said measurement data.

16. The method of claim 11, wherein determining said target flow rate comprises determining a flow rate so as to increase an effective lateral size of said via opening and said trench compared to the lateral size indicated by said measurement data.

17. The method of claim 11, wherein said polymerizing gas comprises carbon, hydrogen and fluorine.

18. A method, comprising:
forming a trench hard mask above a dielectric material of a semiconductor device;
forming a portion of a via opening in said dielectric material through said hard mask opening;
forming a trench in said dielectric material, while increasing a depth of said via opening so as to extend to an etch stop layer; and
adjusting a lateral dimension of said trench by etching through said etch stop layer and controlling at least one process parameter.

19. The method of claim 18, wherein controlling at least one process parameter comprises controlling at least a flow rate of a polymerizing gas when etching through said etch stop layer.

20. The method of claim 18, wherein said dielectric material is an ultra low-k dielectric material of a metallization layer.
